(19) United States
(12) Patent Application Publication
(10) Pub. No.: US 2026/0299646 A1
(43) Pub. Date: Oct. 1, 2026

(54) DISPLAY MODULE AND DISPLAY DEVICE

(71) Applicant: BOE TECHNOLOGY GROUP CO., LTD., Beijing (CN)

(72) Inventors: Yue Cui, Beijing (CN); Hong Zhu, Beijing (CN); Kun Shi, Beijing (CN); Lijuan Zhao, Beijing (CN); Yue Lei, Beijing (CN); Tao Wang, Beijing (CN)

(73) Assignee: BOE TECHNOLOGY GROUP CO., LTD., Beijing (CN)

(21) Appl. No.: 18/992,610

(22) PCT Filed: May 22, 2024
(86) PCT No.: PCT/CN2024/094563

§ 371 Date: Jan. 9, 2025

(30) Foreign Application Priority Data
Jun. 20, 2023 (CN) 202310736065.1

(51) Int. Cl. G06F 1/16

(52) U.S. Cl. CPC G06F 1/1656; G06F 1/1652

(57) ABSTRACT

A display module and a display device are provided. The display module includes a first support layer, a display panel and a cover plate laminated one on another. The first support layer includes a body and an extension member surrounding the body, an orthogonal projection of the display panel onto the first support layer coincides with the body, the extension member is located at an outer side of an edge of the orthogonal projection of the display panel onto the first support layer, and the display module further includes a waterproof layer at least covering a side surface of the display panel and a surface of the extension member proximate to the display panel. According to the present disclosure, it is able to improve the waterproof performance of the display module, thereby to improve the reliability of the display module.

### CROSS-REFERENCE TO RELATED APPLICATION

This application claims a priority of the Chinese patent application No. 202310736065.1 filed on Jun. 20, 2023, which is incorporated herein by reference in its entirety.

### TECHNICAL FIELD

The present disclosure relates to the field of display technology, in particular to a display module and a display device.

### BACKGROUND

Along the development of the display technology, waterproof performance of a display product is highly demanded. It is found that, moisture easily enters a display module from a side surface of the display module, so the waterproof performance of the display module is adversely affected. Especially for a flexible display module, it is impossible to ensure the waterproof performance at the side surface in a case that the flexible display module is in a folded or curved state.

### SUMMARY

An object of the present disclosure is to provide a display module and a display device, so as to solve at least one of the problems in the related art.

In order to achieve the above-mentioned object, the present disclosure provides the following technical solutions.

In one aspect, the present disclosure provides in some embodiments a display module, including a first support layer, a display panel and a cover plate laminated one on another. The first support layer includes a body and an extension member surrounding the body, an orthogonal projection of the display panel onto the first support layer coincides with the body, the extension member is located at an outer side of an edge of the orthogonal projection of the display panel onto the first support layer, and the display module further includes a waterproof layer at least covering a side surface of the display panel and a surface of the extension member proximate to the display panel.

In a possible embodiment of the present disclosure, the waterproof layer further covers a side surface of the first support layer, and/or the waterproof layer further covers a side surface of the cover plate.

In a possible embodiment of the present disclosure, the waterproof layer further covers an edge of a surface of the first support layer distal to the display panel, and/or the waterproof layer further covers an edge of a surface of the cover plate distal to the display panel.

In a possible embodiment of the present disclosure, the display module further includes a second support layer arranged at a side of the first support layer distal to the display panel.

In a possible embodiment of the present disclosure, the waterproof layer further covers side surfaces of the first support layer and the second support layer, and/or the waterproof layer further covers a side surface of the cover plate.

In a possible embodiment of the present disclosure, the waterproof layer further covers an edge of a surface of the second support layer distal to the display panel, and/or the waterproof layer further covers an edge of a surface of the cover plate distal to the display panel.

In a possible embodiment of the present disclosure, at least one first opening is formed at an edge of a surface of the first support layer proximate to the display panel, and a portion of the first opening is located in the extension member.

In a possible embodiment of the present disclosure, the first opening is a blind hole, and a depth of the blind hole is 30% to 50% of a thickness of the first support layer.

In a possible embodiment of the present disclosure, the first opening is a through hole, an edge of an orthogonal projection of the second support layer onto the first support layer is located at an inner side of the edge of the orthogonal projection of the display panel onto the first support layer, and the edge of the orthogonal projection of the second support layer onto the first support layer is located at an outer side of an inner edge of the through hole.

In a possible embodiment of the present disclosure, the first opening is of a rectangular, circular or oval shape.

In a possible embodiment of the present disclosure, a longitudinal section of the first opening is of a rectangular or trapezoidal shape.

In a possible embodiment of the present disclosure, a second opening is further formed in the first support layer, the second opening is a through hole, and the first opening has a same size as the second opening.

In a possible embodiment of the present disclosure, the waterproof layer is a waterproof adhesive or a waterproof adhesive tape.

In a possible embodiment of the present disclosure, the waterproof adhesive has an elastic modulus of 1 Mpa to 5 Mpa, and/or the waterproof adhesive has an elongation at break of greater than or equal to 400%.

In a possible embodiment of the present disclosure, the display module is a flexible display module.

In another aspect, the present disclosure provides in some embodiments a display device, including the above-mentioned display module.

The present disclosure has the following beneficial effects.

According to the embodiments of the present disclosure, it is able to improve the waterproof performance of the display module, thereby to improve the reliability of the display module. Especially, for a flexible display module, it is able to ensure the waterproof performance at a side surface in a case that the flexible display module is in a folded or curved state.

### BRIEF DESCRIPTION OF THE DRAWINGS

The present disclosure will be described hereinafter in details in conjunction with the drawings and embodiments.

FIG. 1 is a top view of a flexible display module according to a first embodiment of the present disclosure;

FIG. 2 is a sectional view of the flexible display module along line A-A in FIG. 1;

FIGS. 3 to 5 are sectional views of the flexible display module at different stages of a manufacture process according to the first embodiment of the present disclosure;

FIG. 6 is a top view of the flexible display module according to a second embodiment of the present disclosure;

FIG. 7 is a sectional view of the flexible display module along line B-B in FIG. 6;

FIG. 8 is a sectional view of the flexible display module along line C-C in FIG. 6;

FIG. 9 is a top view of the flexible display module according to a third embodiment of the present disclosure;

FIG. 10 is a sectional view of the flexible display module along line D-D in FIG. 9;

FIG. 11 is a sectional view of the flexible display module along line E-E in FIG. 9; and

FIG. 12 is a sectional view of the flexible display module according to a fourth embodiment of the present disclosure.

### DETAILED DESCRIPTION OF THE EMBODIMENTS

The expressions “arranged on”, “formed on” and “located on” are used to indicate that one layer is directly formed or arranged on another layer, or one layer is indirectly formed or arranged on another layer, i.e., there is any other layer between the two layers.

It should be appreciated that, such words as “first” and “second” are used to describe various members, components, elements, regions, layers and/or portions, but the members components, elements, regions, layers and/or portions shall not be limited by these words. In addition, these words are used to differentiate one member, component, element, region, layer and/or portion from the other. Hence, a first member, a first component, a first element, a first region, a first layer and/or a first portion discussed hereinafter may also be called as second member, second component, second element, second region, second layer and/or second portion, without departing from the teaching of the present disclosure.

In the embodiments of the present disclosure, unless otherwise defined, the expression “arranged at a same layer” refers to that two layers, members, components, elements or portions are formed through a same manufacture process (e.g., patterning process), and usually the two layers, members, components, elements or portions are made of a same material. For example, in a case that two or more functional layers are arranged at a same layer, it means that these functional layers are made of a same material and through a same manufacture process, so as to simplify the manufacture of a display substrate.

In the embodiments of the present disclosure, unless otherwise defined, the term “patterning process” usually includes such steps as coating, exposing, developing, etching and removing a photoresist. The term “single patterning process” refers that a patterned layer, component or member is formed through one mask.

It is found that, moisture easily enters a display module from a side surface of the display module, so the waterproof performance of the display module is adversely affected. Especially for a flexible display module, it is impossible to ensure the waterproof performance at the side surface in a case that the flexible display module is in a folded or curved state.

In order to solve the above problem, the present disclosure provides in some embodiments a display module, which includes a first support layer, a display panel and a cover plate laminated one on another. The first support layer includes a body and an extension member surrounding the body, an orthogonal projection of the display panel onto the first support layer coincides with the body, the extension member is located at an outer side of an edge of the orthogonal projection of the display panel onto the first support layer, and the display module further includes a waterproof layer at least covering a side surface of the display panel and a surface of the extension member proximate to the display panel.

In the embodiments of the present disclosure, the waterproof layer is attached to and encapsulates the side surface of the display panel, so as to improve the waterproof performance of the display module, thereby to improve the reliability of the display module. In addition, the first support layer at a backlight side of the display panel is designed to have the extension member and the waterproof layer covers a surface of the extension member proximate to the display panel, so as to increase an attachment area of the waterproof layer, and increase an adhesion force between the waterproof layer and the display module, thereby to further increase the waterproof performance of the display module and prevent the waterproof layer from peeling off. The scheme in the embodiments of the present disclosure is particularly suitable for a flexible display module, so as to ensure the waterproof performance at the side surface in a case that the flexible display module is in a folded or curved state.

The display module will be described hereinafter through first to fourth embodiments taking an Organic Light-Emitting Diode (OLED) flexible display module as an example. It should be appreciated that, the present disclosure is not limited thereto. For example, the display module may also be a Micro Light-Emitting Diode (LED) flexible display module, or a Mini LED flexible display module.

### First Embodiment

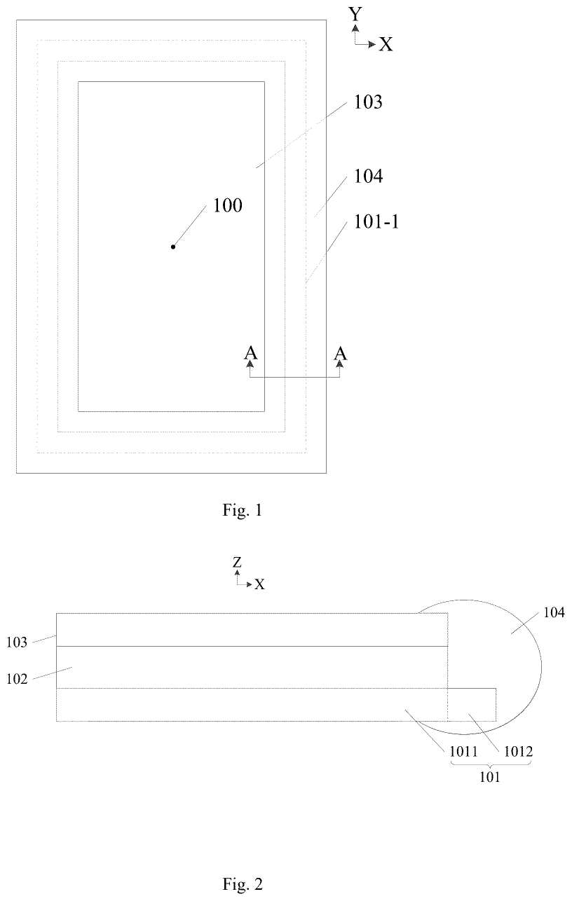

As shown in FIGS. 1 and 2, the OLED flexible display module in this embodiment includes a first support layer 101, an OLED display panel 102 and a cover plate 103 laminated one on another. The first support layer 101 includes a body 1011 and an extension member 1012 surrounding the body 1011, an orthogonal projection of the OLED display panel 102 onto the first support layer 101 coincides with the body 1011, and the extension member 1012 is arranged at an outer side of an edge of the orthogonal projection of the OLED display panel 102 onto the first support layer 101. In this embodiment of the present disclosure, the display module further includes a waterproof layer 104 at least covering a side surface of the OLED display panel 102 and a surface of the extension member 1012 proximate to the OLED display panel 102. In FIG. 1, a dotted line 101-1 indicates a contour of an edge of the first support layer 101, or a contour of an outer edge of the extension member 1012. The outer edge of the extension member 1012 is an edge of the extension member 1012 distal to a center 100 of the OLED display panel 102. In FIG. 2, a dotted line in the first support layer 101 is a boundary between the body 1011 and the extension member 1012.

As shown in FIG. 2, in the first embodiment of the present disclosure, the waterproof layer 104 is attached to and encapsulates the side surface of the OLED display panel 102, so as to improve the waterproof performance of the OLED flexible display module, thereby to improve the reliability of the OLED flexible display module. In addition, the first support layer 101 has the extension member 1012 and the waterproof layer 104 covers a surface of the extension member 1012 proximate to the OLED display panel 102, so as to increase an attachment area of the waterproof layer 104, and increase an adhesion force between the waterproof layer 104 and the OLED flexible display module, thereby to further increase the waterproof performance of the OLED flexible display module and prevent the waterproof layer 104 from peeling off. In a word, it is able to ensure the waterproof performance at the side surface of the OLED flexible display module in a case that the OLED flexible display module is in a folded or curved state.

It should be appreciated that, sizes of the film layers in FIGS. 1 and 2 are for illustrative purposes only, but do not reflect an actual size or a relative scale, so do the other figures.

In the OLED flexible display module in FIGS. 1 and 2, the first support layer 101 having a support and protection function is arranged at a backlight side of the OLED display panel 102, and the cover plate 103 is arranged at a light-exiting side of the OLED display panel 102. For example, the first support layer 101 may be a metallic support layer, and the cover plate 103 may be a flexible cover plate made of colorless polyimide (CPI), polyethylene naphthalate (PEN), thermoplastic polyester (e.g., polyethylene terephthalate (PET)), or a combination thereof.

For example, the OLED flexible display module In FIGS. 1 and 2 further includes a polarizer (POL) and Ultra Thin Glass (UTG) arranged between the OLED display panel 102 and the cover plate 103. For example, in a case of no polarizer, the cover plate 103 is adhered to the OLED display panel 102 through an optically clear adhesive (OCA). In a case of the polarizer and the UTG, the cover plate 103 is adhered to the UTG, the UTG is adhered to the polarizer through an OCA, and the polarizer is adhered to the OLED display panel 102 through an OCA. For example, a thickness of the cover plate 103 (a length of the cover plate 103 in a direction Z, i.e., a direction perpendicular to a light-exiting surface of the OLED display panel 102 in FIG. 2) is 50 μm to 100 μm, e.g., 50 μm, 66 μm, 85 μm, 92 μm or 100 μm. For example, a thickness of the UTG is 50 μm to 100 μm, e.g., 50 μm, 65 μm, 82 μm, 90 μm or 100 μm. A thickness of the OCA is 25 μm to 100 μm, e.g., 25 μm, 47 μm, 62 μm, 83 μm or 100 μm. For example, edges of the OLED display panel 102, the cover plate 103, the polarizer, the UTG and the OCA are flush with each other, i.e., orthogonal projections of the OLED display panel 102, the cover plate 103, the polarizer, the UTG and the OCA onto the first support layer 101 coincide with each other. In addition, an edge of the UTG is indented, i.e., the orthogonal projections of the OLED display panel 102, the cover plate 103, the polarizer and the OCA onto the first support layer 101 coincide with each other, and an edge of the orthogonal projection of the UTG onto the first support layer 101 is located at an inner side of an edge of the orthogonal projection of the OLED display panel 102 onto the first support layer 101.

For example, a length of a portion of the first support layer 101 extending beyond the OLED display panel 102, i.e., a length of the extension member 1012 in a direction from a center 100 of the OLED display panel 102 to an edge of the OLED display panel 102 (i.e., in a direction X in FIG. 2), is set as 0.3 mm to 1 mm, e.g., 0.3 mm, 0.5 mm, 0.75 mm, 0.88 mm or 1 mm. In this way, it is able to prevent the waterproof layer 104 from peeling off while improving the waterproof performance of the OLED flexible display module. In addition, the length of the extension member 1012 in the direction X is set as 0.3 mm to 1 mm by considering such factors as an attachment tolerance, a material tolerance and an assembling tolerance. It should be appreciated that, in FIGS. 1 and 2, the OLED flexible display module is in an unfolded state, and the direction from the center 100 to the edge of the OLED display panel 102 is just a direction viewed in a case that the OLED flexible display module is in the unfolded state.

As shown in FIG. 2, in the OLED flexible display module in the first embodiment of the present disclosure, the waterproof layer 104 further covers a side surface of the first support layer 101 and a side surface of the cover plate 103. In this way, it is able to further improve an attachment and encapsulation effect of the waterproof layer 104, thereby to further improve the waterproof performance of the OLED flexible display module. In addition, an attachment area is increased, so as to prevent the waterproof layer 104 from peeling off.

As shown in FIG. 2, in the OLED flexible display module in the first embodiment of the present disclosure, the waterproof layer 104 further covers an edge of a surface of the first support layer 101 distal to the OLED display panel 102, and further covers an edge of a surface of the cover plate 103 distal to the OLED display panel 102. In this way, it is able to further improve an attachment and encapsulation effect of the waterproof layer 104, thereby to further improve the waterproof performance of the OLED flexible display module. In addition, an attachment area is increased, so as to prevent the waterproof layer 104 from peeling off. It should be appreciated that, the OLED flexible display module further includes a polarizer and UTG arranged between the OLED display panel 102 and the cover plate 103, so the waterproof layer 104 further covers side surfaces of the polarizer and the UTG.

As shown in FIG. 2, in the OLED flexible display module in the first embodiment of the present disclosure, the waterproof layer 104 is a waterproof adhesive.

To be specific, the waterproof adhesive has a maximum thickness of 1 mm to 3 mm, e.g., 1 mm, 1.5 mm, 2.1 mm, 2.5 mm or 3 mm. The thickness of the waterproof adhesive is a length of the waterproof adhesive in the direction from the center 100 to the edge of the OLED display panel 102 (i.e., the direction X in FIG. 2). In this way, the length of the waterproof adhesive in the direction X is greater than the length of the portion of the first support layer 101 extending beyond the OLED display panel 102, so that the waterproof adhesive forms a full wrapping structure at the side surface of the OLED flexible display module. For example, the waterproof adhesive includes, but not limited to, a high molecular material such as silica gel or organic resin.

In the OLED flexible display module in the first embodiment of the present disclosure, the waterproof adhesive has an elastic modulus of 1 Mpa to 5 Mpa, e.g., 1 Mpa, 2 Mpa, 3.4 Mpa, 4.2 Mpa or 5 Mpa. The waterproof adhesive has an elongation at break greater than or equal to 400%, e.g., 400%, 450%, 520%, 600% or 680%. In this way, it is able to ensure the stretchability and the bending resistance of the waterproof adhesive. For example, in the elastic modulus of the waterproof adhesive is 1 Mpa to 5 Mpa, it is able to ensure the adhesion performance of the waterproof adhesive, and prevent the waterproof adhesive from peeling off even in a case that the OLED flexible display module is bent for more than 10,000 times.

To be specific, based on the above, the OLED flexible display module in the first embodiment of the present disclosure is manufactured as follows.

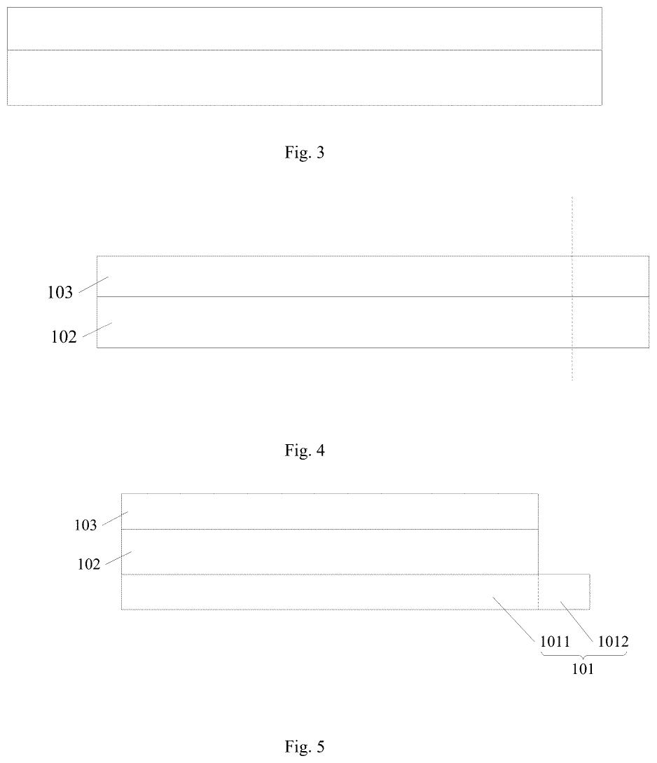

At first, the cover plate is adhered to a light-exiting side of the OLED display panel through an OCA, so as to obtain a structure in FIG. 3.

Next, the structure in FIG. 3 is subjected to edge-cutting through, e.g., a laser beam, so as to obtain a structure in FIG. 4 in which edges of the cover plate 103, the OCA and the OLED display panel 102 are flush with each other. A dotted line in FIG. 4 represents a cutting line.

Then, the first support layer 101 is attached to a backlight side of the OLED display panel 102, so as to obtain a structure in FIG. 5. In FIG. 5, the first support layer 101 extends beyond the OLED display panel 102.

Finally, the waterproof adhesive is applied to the side surfaces of the cover plate 103, the OLED display panel 102 and the first support layer 101 through an adhesive application device, so as to obtain the OLED flexible display module in FIG. 2.

### Second Embodiment

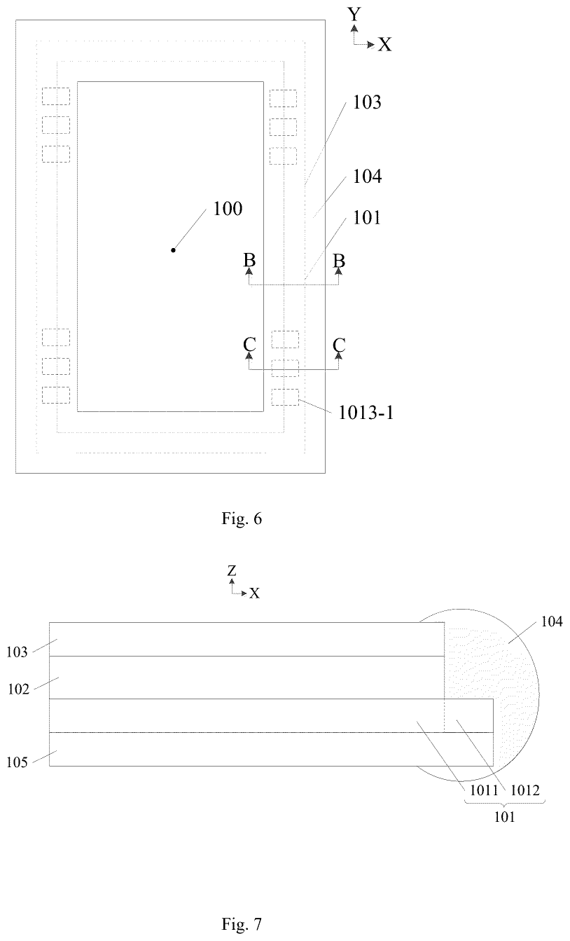

As shown in FIGS. 6 to 8, different from the OLED flexible display module in the first embodiment, the OLED flexible display module in the second embodiment further includes a second support layer 105 arranged at a side of the first support layer 101 distal to the OLED display panel 102. For example, the second support layer 105 is a metallic support layer.

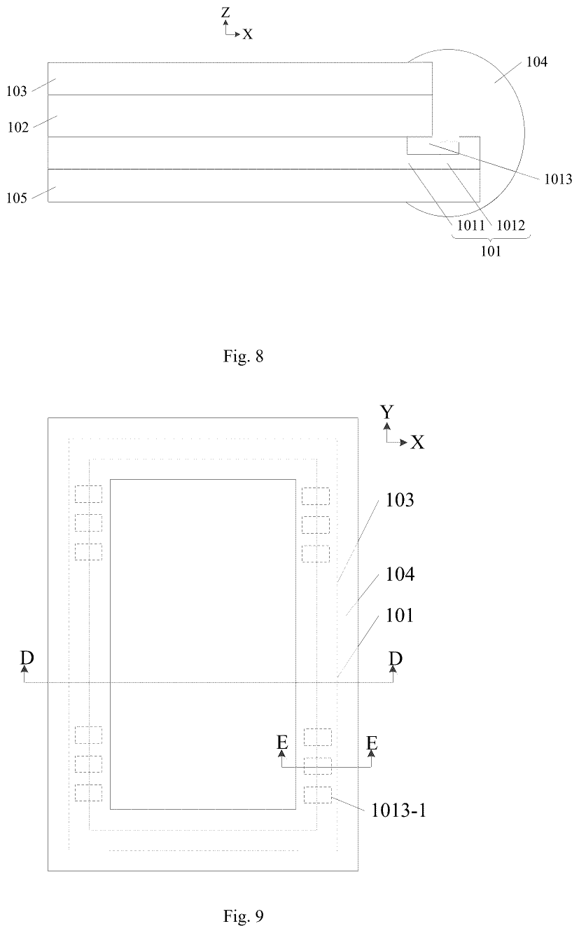

As shown in FIGS. 7 and 8, in the OLED flexible display module in the second embodiment of the present disclosure, the waterproof layer 104 further covers side surfaces of the first support layer 101, the second support layer 105 and the cover plate 103. In this way, it is able to further improve an attachment and encapsulation effect of the waterproof layer 104, thereby to further improve the waterproof performance of the OLED flexible display module. In addition, an attachment area is increased, so as to prevent the waterproof layer 104 from peeling off.

As shown in FIGS. 7 and 8, in the OLED flexible display module in the second embodiment of the present disclosure, the waterproof layer 104 further covers an edge of a surface of the second support layer 105 distal to the OLED display panel 102, and an edge of a surface of the cover plate 103 distal to the OLED display panel 102. In this way, it is able to further improve an attachment and encapsulation effect of the waterproof layer 104, thereby to further improve the waterproof performance of the OLED flexible display module. In addition, an attachment area is increased, so as to prevent the waterproof layer 104 from peeling off.

To be specific, as shown in FIGS. 7 and 8, the edge of the first support layer 101 is flush with the edge of the second support layer 105, i.e., an orthogonal projection of the first support layer 101 in a direction Z overlaps with an orthogonal projection of the second support layer 105 in the direction Z.

As shown in FIGS. 6 and 8, in the OLED flexible display module in the second embodiment of the present disclosure, at least a first opening 1013 is formed at an edge of a surface of the first support layer 101 proximate to the OLED display panel 102, and a portion of the first opening 1013 is located at the extension member 1012. As shown in FIG. 8, a portion of the first opening 1013 is located at the extension member 1012, i.e., a portion of the first opening 1013 is located at an edge of the body 1011 and another portion of the first opening 1013 is located at an inner edge of the extension member 1012. The inner edge of the extension member 1012 is an edge of the extension member 1012 proximate to the center 100 of the OLED display panel 102. In FIG. 6, a dotted line 1013-1 indicates a contour of an edge of the first opening 1013.

In a case that the waterproof adhesive is applied, the fluidic waterproof adhesive flows into the first opening 1013 from above, so as to be in contact with the first support layer 101. In this way, it is able to increase a contact area between the waterproof adhesive and the first support layer 101, thereby to prevent the waterproof adhesive from peeling off while improving the waterproof performance of the OLED flexible display module.

For example, as shown in FIG. 6, a plurality of first openings 1013 is formed in each of four corner regions of the approximately-rectangular first support layer 101 and arranged in a direction Y, and the direction Y is perpendicular to the direction X in a plane parallel to the OLED display panel 102. A distance between the adjacent first openings 1013 is 1 mm to 10 mm, e.g., 1 mm, 3 mm, 5 mm, 7.5 mm or 10 mm. It should be appreciated that, the positions, the arrangement modes and the quantity of the first openings 1013 in FIG. 6 are for illustrative purposes only, and they may be set according to a size of the display module, a thickness of each film layer, precision of the manufacture process and the fluidity of the waterproof adhesive.

For example, as shown in FIG. 8, the first opening 1013 is a blind hole, and a depth of the blind hole is 30% to 50%, e.g., 30%, 35%, 40%, 44% or 50%, of a thickness of the first support layer 101.

For example, a distance between an outer edge of the first opening 1013 and an edge of the first support layer 101 (i.e., an outer edge of the extension member 1012) is 0.1 mm to 0.5 mm, e.g., 0.1 mm, 0.2 mm, 0.35 mm, 0.42 mm or 0.5 mm.

In a possible embodiment of the present disclosure, the first opening is of, but not limited to, a rectangular, circular or oval shape, and a specific shape of the first opening may be selected according to the practical need. In FIG. 6, the first opening 1013 is of a rectangular shape.

In a possible embodiment of the present disclosure, a longitudinal section of the first opening is of a rectangular or trapezoidal shape. In FIG. 6, the longitudinal section of the first opening 1013 is of a rectangular shape.

In a possible embodiment of the present disclosure, a second opening (not shown) is further formed in the first support layer 101, the second opening is a through hole, and the first opening has a same size as the second opening. The first support layer 101 includes an opening region and a flat plate region, and the second opening is used to increase the bending performance, so as to improve the stretchability and the bending resistance of the first support layer 101. The second opening is formed at the opening region of the first support layer 101, and the first opening 1013 is formed at the flat plate region of the first support layer 101. In a case that the first opening 1013 has a same size as the second opening, it is able to ensure the stability of a hole-forming process, e.g., an etching process. In addition, the first opening 1013 and the second opening are formed simultaneously through a same hole-forming process, so as to simplify the manufacture process.

### Third Embodiment

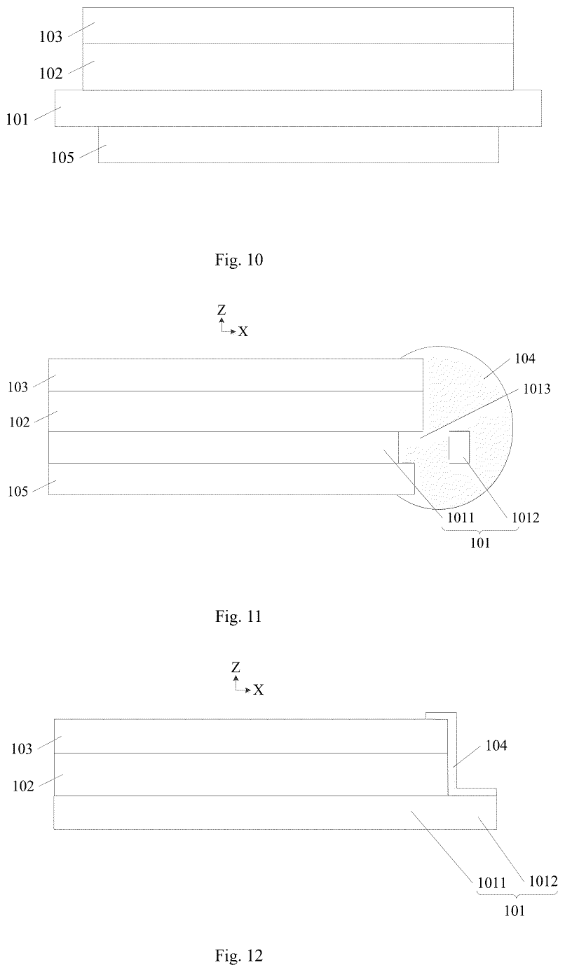

As shown in FIGS. 9 to 11, different from the OLED flexible display module in the second embodiment, in the second embodiment, the first opening 1013 is a through hole, an edge of an orthogonal projection of the second support layer 105 onto the first support layer 101 is located at an inner side of the edge of the orthogonal projection of the OLED display panel 102 onto the first support layer 101, and the edge of the orthogonal projection of the second support layer 105 onto the first support layer 101 is located at an outer side of an inner edge of the first opening 1013. The inner edge of the first opening 1013 is an edge of the first opening 1013 proximate to the center 100 of the OLED display panel 102. In other words, the first support layer 101 extends beyond the OLED display panel 102, and the second support layer 105 is indented relative to the OLED display panel 102 in such a manner as not to go beyond the inner edge of the first opening 1013.

In a case that the waterproof adhesive is applied, the fluidic waterproof adhesive flows into the first opening 1013 from above and bottom, so as to be in contact with the first support layer 101 and the second support layer 105. In this way, it is able to increase a contact area between the waterproof adhesive and the first support layer 101 and a contact area between the waterproof adhesive and the second support layer 105, thereby to prevent the waterproof adhesive from peeling off while improving the waterproof performance of the OLED flexible display module. In addition, in a case that the second support layer 105 is indented in such a manner as not to go beyond the inner edge of the first opening 1013, it is able to improve the support at an edge of the display module.

For example, a length of the first opening 1013 in the direction from the center to the edge of the OLED display panel 102 (i.e., the direction X in FIG. 11) is 2.6 mm±0.3 mm, considering such factors as an attachment tolerance and a dimension tolerance. A distance between an outer edge of the first opening 1013 and an edge of the first support layer 101 (i.e., an outer edge of the extension member 1012) is 0.1 mm to 0.5 mm, e.g., 0.1 mm, 0.2 mm, 0.35 mm, 0.42 mm or 0.5 mm. Considering such factors as an attachment tolerance, a material tolerance and an assembling tolerance, a length of a portion of the first support layer 101 extending beyond the OLED display panel 102 is 0.3 mm to 1 mm, e.g., 0.3 mm, 0.5 mm, 0.75 mm, 0.88 mm or 1 mm. Considering such factors as an attachment tolerance, a machining tolerance and fluidity of the waterproof adhesive, the second support layer 105 is indented relative to the OLED display panel 102 by 0.75 mm±0.3 mm. Based on the above parameters, the fluidic waterproof adhesive flows into the first opening 1013 from above and bottom, so as to be in contact with the first support layer 101 and the second support layer 105. In this way, it is able to increase a contact area between the waterproof adhesive and the first support layer 101 and a contact area between the waterproof adhesive and the second support layer 105, thereby to prevent the waterproof adhesive from peeling off while improving the waterproof performance of the OLED flexible display module. In addition, in a case that the second support layer 105 is indented in such a manner as not to go beyond the inner edge of the first opening 1013, it is able to improve the support at an edge of the display module.

### Fourth Embodiment

As shown in FIG. 12, different from the OLED flexible display module in the first embodiment, in the fourth embodiment, the waterproof layer 104 is a waterproof adhesive tape.

As shown in FIG. 12, the waterproof adhesive tape covers an edge of a surface of the cover plate 103 distal to the OLED display panel 102, a side surface of the cover plate 103, a side surface of the OLED display panel 102, and a surface of the extension member 1012 proximate to the OLED display panel 102.

In addition, the waterproof adhesive tape further covers a side surface of the first support layer 101, a side surface of the cover plate 103, an edge of a surface of the first support layer 101 distal to the OLED display panel 102, and an edge of a surface of the cover plate 103 distal to the OLED display panel 102.

The present disclosure further provides in some embodiments a display device, which includes the above-mentioned OLED flexible display module. The display device may be any product or member having a display function, e.g., mobile phone, tablet computer or digital photo frame, which will not be particularly defined herein.

Obviously, the above embodiments are merely used to illustratively describe the present disclosure, but shall not be construed as limiting the present disclosure. A person skilled in the art may make alterations or modifications based on the above description, and these alterations or modifications shall also fall within the scope of the present disclosure.

1. A display module, comprising a first support layer, a display panel and a cover plate laminated one on another, wherein the first support layer includes a body and an extension member surrounding the body, an orthogonal projection of the display panel onto the first support layer coincides with the body, the extension member is located at an outer side of an edge of the orthogonal projection of the display panel onto the first support layer, and the display module further includes a waterproof layer at least covering a side surface of the display panel and a surface of the extension member proximate to the display panel.

2. The display module according to claim 1, wherein the waterproof layer further covers a side surface of the first support layer, and/or the waterproof layer further covers a side surface of the cover plate.

3. The display module according to claim 2, wherein the waterproof layer further covers an edge of a surface of the first support layer distal to the display panel, and/or the waterproof layer further covers an edge of a surface of the cover plate distal to the display panel.

4. The display module according to claim 1, further comprising a second support layer arranged at a side of the first support layer distal to the display panel.

5. The display module according to claim 4, wherein the waterproof layer further covers side surfaces of the first support layer and the second support layer, and/or the waterproof layer further covers a side surface of the cover plate.

6. The display module according to claim 5, wherein the waterproof layer further covers an edge of a surface of the second support layer distal to the display panel, and/or the waterproof layer further covers an edge of a surface of the cover plate distal to the display panel.

7. The display module according to claim 4, wherein at least one first opening is formed at an edge of a surface of the first support layer proximate to the display panel, and a portion of the first opening is located in the extension member.

8. The display module according to claim 7, wherein the first opening is a blind hole, and a depth of the blind hole is 30% to 50% of a thickness of the first support layer.

9. The display module according to claim 7, wherein the first opening is a through hole, an edge of an orthogonal projection of the second support layer onto the first support layer is located at an inner side of the edge of the orthogonal projection of the display panel onto the first support layer, and the edge of the orthogonal projection of the second support layer onto the first support layer is located at an outer side of an inner edge of the through hole.

10. The display module according to claim 7, wherein the first opening is of a rectangular, circular or oval shape.

11. The display module according to claim 7, wherein a longitudinal section of the first opening is of a rectangular or trapezoidal shape.

12. The display module according to claim 7, wherein a second opening is further formed in the first support layer, the second opening is a through hole, and the first opening has a same size as the second opening.

13. The display module according to claim 4, wherein the waterproof layer is a waterproof adhesive or a waterproof adhesive tape.

14. The display module according to claim 13, wherein the waterproof adhesive has an elastic modulus of 1 Mpa to 5 Mpa, and/or the waterproof adhesive has an elongation at break of greater than or equal to 400%.

15. The display module according to claim 1, wherein the display module is a flexible display module.

16. A display device, comprising a display module, wherein the display module comprises a first support layer, a display panel and a cover plate laminated one on another, wherein the first support laver includes a body and an extension member surrounding the body, an orthogonal projection of the display panel onto the first support layer coincides with the body, the extension member is located at an outer side of an edge of the orthogonal projection of the display panel onto the first support layer, and the display module further includes a waterproof layer at least covering a side surface of the display panel and a surface of the extension member proximate to the display panel.

17. The display device according to claim 16, wherein the waterproof layer further covers a side surface of the first support layer, and/or the waterproof layer further covers a side surface of the cover plate.

18. The display device according to claim 17, wherein the waterproof layer further covers an edge of a surface of the first support layer distal to the display panel, and/or the waterproof layer further covers an edge of a surface of the cover plate distal to the display panel.

19. The display device according to claim 16, wherein the display module further comprises a second support layer arranged at a side of the first support layer distal to the display panel.

20. The display device according to claim 19, wherein the waterproof layer further covers side surfaces of the first support layer and the second support layer, and/or the waterproof layer further covers a side surface of the cover plate.
